(19) United States
(12) Patent Application Publication
(10) Pub. No.: US 2026/0180569 A1
(43) Pub. Date: Jun. 25, 2026

(54) SEMICONDUCTOR DEVICE, CONTROL CIRCUIT, CONTROL METHOD, AND STORAGE MEDIUM

(71) Applicants: Kabushiki Kaisha Toshiba, Kawasaki-shi (JP); Toshiba Electronic Devices & Storage Corporation, Kawasaki-shi (JP)

(72) Inventors: Toru SUGIYAMA, Musashino Tokyo (JP); Noriaki YOSHIKAWA, Inagi Tokyo (JP)

(21) Appl. No.: 19/447,972

(22) Filed: Jan. 13, 2026

Related U.S. Application Data
(63) Continuation of application No. PCT/JP2024/015442, filed on Apr. 18, 2024.

(51) Int. Cl. H03K 17/082; H03K 17/0812

(52) U.S. Cl. CPC H03K 17/0822; H03K 17/08122; H03K 17/0828

(57) ABSTRACT

A semiconductor device according to an embodiment includes a first semiconductor element of normally-on, a second semiconductor element of p-type MOSFET, and a control circuit. If a potential of a second source terminal of the second semiconductor element is not less than a potential of a second drain terminal of the second semiconductor element, the control circuit applies a first voltage to a connection point between a first source terminal of the first semiconductor element and the second source terminal. If the potential of the second source terminal is less than the potential of the second drain terminal, the control circuit applies a second voltage to the connection point. The second voltage is less than the first voltage. A difference between the second voltage and a voltage applied to a second gate terminal of the second semiconductor element is greater than a threshold voltage of the second semiconductor element.

### CROSS-REFERENCE TO RELATED APPLICATIONS

This is a continuation application of International Patent Application PCT/JP2024/015442, filed on Apr. 18, 2024. The entire contents of which are incorporated herein by reference.

### FIELD

Embodiments described herein relate generally to a semiconductor device, a control circuit, a control method, and a storage medium.

### BACKGROUND

There is a semiconductor device that includes a semiconductor element, and a control circuit that controls the semiconductor element. Technology that can reduce the power consumption is desirable for semiconductor devices.

### BRIEF DESCRIPTION OF THE DRAWINGS

FIG. 1 is a schematic view showing a configuration of a semiconductor device according to an embodiment;

FIG. 2 is a circuit diagram showing a configuration of an electrical circuit according to an embodiment;

FIG. 3 is a timing chart showing a control of the electrical circuit according to the embodiment;

FIG. 4 is a schematic view showing a flow of a current in the electrical circuit according to the embodiment;

FIG. 5 is a schematic view showing a flow of a current in the electrical circuit according to the embodiment;

FIG. 6 is a schematic view showing a flow of a current in the electrical circuit according to the embodiment;

FIG. 7 is a schematic view showing a flow of a current in the electrical circuit according to the embodiment; and

FIG. 8 is a graph showing characteristics of a first semiconductor element.

### DETAILED DESCRIPTION

A semiconductor device according to an embodiment includes a first semiconductor element, a second semiconductor element, and a control circuit. The first semiconductor element includes a first source terminal, a first drain terminal, and a first gate terminal. The first semiconductor element is normally-on. The second semiconductor element includes a second source terminal, a second drain terminal, and a second gate terminal; and the second source terminal is electrically connected to the first source terminal. The second semiconductor element is a p-type MOSFET. The control circuit is electrically connected to a connection point between the first source terminal and the second source terminal. In a first state in which a potential of the second source terminal is not less than a potential of the second drain terminal, the control circuit applies a first voltage to the connection point. In a second state in which the potential of the second source terminal is less than the potential of the second drain terminal, the control circuit applies a second voltage to the connection point. In the second state, the second voltage is less than the first voltage; and an absolute value of a difference between the second voltage and a voltage applied to the second gate terminal is greater than an absolute value of a threshold voltage of the second semiconductor element.

Exemplary embodiments will now be described with reference to the drawings. The drawings are schematic or conceptual; and the relationships between the thickness and width of portions, the proportional coefficients of sizes among portions, etc., are not necessarily the same as the actual values thereof. In the specification of the application and the drawings, components similar to those described in regard to a drawing thereinabove are marked with like reference numerals, and a detailed description is omitted as appropriate.

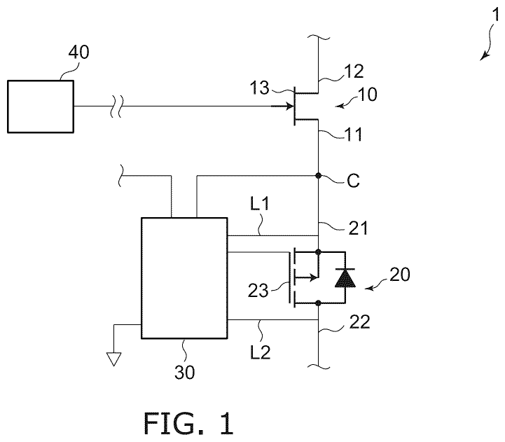

FIG. 1 is a schematic view showing a configuration of a semiconductor device according to an embodiment.

As shown in FIG. 1, the semiconductor device 1 according to the embodiment includes a first semiconductor element 10, a second semiconductor element 20, and a control circuit 30. The first semiconductor element is a normally-on semiconductor element (transistor). The second semiconductor element 20 is a p-type MOSFET.

The first semiconductor element 10 includes a first source terminal 11, a first drain terminal 12, and a first gate terminal 13. The second semiconductor element 20 includes a second source terminal 21, a second drain terminal 22, and a second gate terminal 23. The first source terminal 11 and the second source terminal 21 are electrically connected to each other. The potential of the first source terminal 11 is substantially equal to the potential of the second source terminal 21. The first semiconductor element 10 and the second semiconductor element 20 have a cascode connection.

The control circuit 30 is electrically connected to a connection point C between the first source terminal 11 and the second source terminal 21. The control circuit 30 can control the potential of the connection point C and the potential of the second gate terminal 23. The control circuit 30 is electrically connected to the second source terminal 21 and the second drain terminal 22 respectively by wiring parts L1 and L2, and can detect the potential of the second source terminal 21 and the potential of the second drain terminal 22. The control circuit 30 includes a central processing unit (CPU), memory, etc.

The first gate terminal 13 is electrically connected to a gate drive circuit 40 outside the semiconductor device 1. The potential of the first gate terminal 13 is controlled by the gate drive circuit 40.

The first semiconductor element 10 is normally-on. Therefore, the first semiconductor element 10 is switched to an on-state when the negative voltage of the first gate terminal 13 relative to the first source terminal 11 is not less than a threshold. The first semiconductor element 10 is switched to an off-state when the negative voltage of the first gate terminal 13 relative to the first source terminal 11 is less than the threshold. Herein, the negative voltage being not less than the threshold refers to a state in which a negative voltage value is nearer zero than the threshold. For example, when the threshold is −12 V and the negative voltage of the first gate terminal 13 is in the range of −10 V to 0 V, the negative voltage is not less than the threshold.

The second semiconductor element 20 is a p-type MOSFET. Therefore, the second semiconductor element 20 is switched to the on-state when the negative voltage of the second gate terminal 23 relative to the second source terminal 21 is less than the threshold. The second semiconductor element 20 is switched to the off-state when the negative voltage of the second gate terminal 23 relative to the second source terminal 21 is not less than the threshold.

For example, a voltage is applied to the first drain terminal 12 from an external power supply. A current flows in the first and second semiconductor elements 10 and 20 when both the first and second semiconductor elements 10 and 20 are in the on-state. When the first semiconductor element 10 is in the on-state and the second semiconductor element 20 is in the off-state, a current does not flow in the second semiconductor element 20; and the potential of the first source terminal 11 increases. The negative voltage of the first gate terminal 13 relative to the first source terminal 11 drops below the threshold; and the first semiconductor element 10 also is switched to the off-state. Subsequently, a first voltage that is greater than the absolute value of the threshold of the first semiconductor element 10 is applied to the connection point C via the control circuit 30; and the first semiconductor element 10 is maintained in the off-state. Subsequently, the second semiconductor element 20 is turned on by the control circuit 30 setting the negative voltage of the second gate terminal 23 relative to the second source terminal 21 of the second semiconductor element 20 to be less than the threshold voltage of the second semiconductor element 20. In this state, the first gate terminal 13 of the first semiconductor element 10 is controlled by the gate drive circuit 40 to switch the first semiconductor element 10 with the second semiconductor element 20 in the on-state. The flow of the current in the semiconductor device 1 can be controlled by the switching of the first semiconductor element 10.

The control circuit 30 can determine a first state, in which the potential of the second source terminal 21 is not less than the potential of the second drain terminal 22, and a second state, in which the potential of the second source terminal 21 is less than the potential of the second drain terminal 22. In the first state, a current can flow from the first semiconductor element 10 toward the second semiconductor element 20. In the second state, a current can flow from the second semiconductor element 20 toward the first semiconductor element 10. The second state occurs during reverse recovery after the second semiconductor element 20 is turned off.

In the first state, the control circuit 30 applies the first voltage to the connection point C. The first semiconductor element 10 is in the on-state when the absolute value of the difference between the first voltage and the potential applied to the first gate terminal 13 by the gate drive circuit 40 is less than the absolute value of the threshold of the first semiconductor element 10. The first semiconductor element 10 is in the off-state when the absolute value of the difference between the first voltage and the voltage applied to the first gate terminal 13 by the gate drive circuit 40 is greater than the absolute value of the threshold voltage of the first semiconductor element 10.

In the second state, the control circuit 30 applies the second voltage to the connection point C. The second voltage is less than the first voltage. At this time, the absolute value of the difference between the second voltage and the potential applied to the first gate terminal 13 by the gate drive circuit 40 is less than the absolute value of the threshold voltage of the first semiconductor element 10. Therefore, the first semiconductor element 10 is switched to the on-state. On the other hand, the absolute value of the difference between the second voltage and the voltage applied to the second gate terminal 23 by the control circuit 30 is greater than the absolute value of the threshold voltage of the second semiconductor element 20. Therefore, the second semiconductor element 20 is in the on-state. In the second state, a reverse current may flow in the first semiconductor element 10. For example, the voltage drop that occurs in the first semiconductor element 10 when a current flows from the second semiconductor element 20 toward the first semiconductor element 10 due to the first semiconductor element 10 being turned off is reduced by the first semiconductor element 10 being temporarily switched to the on-state.

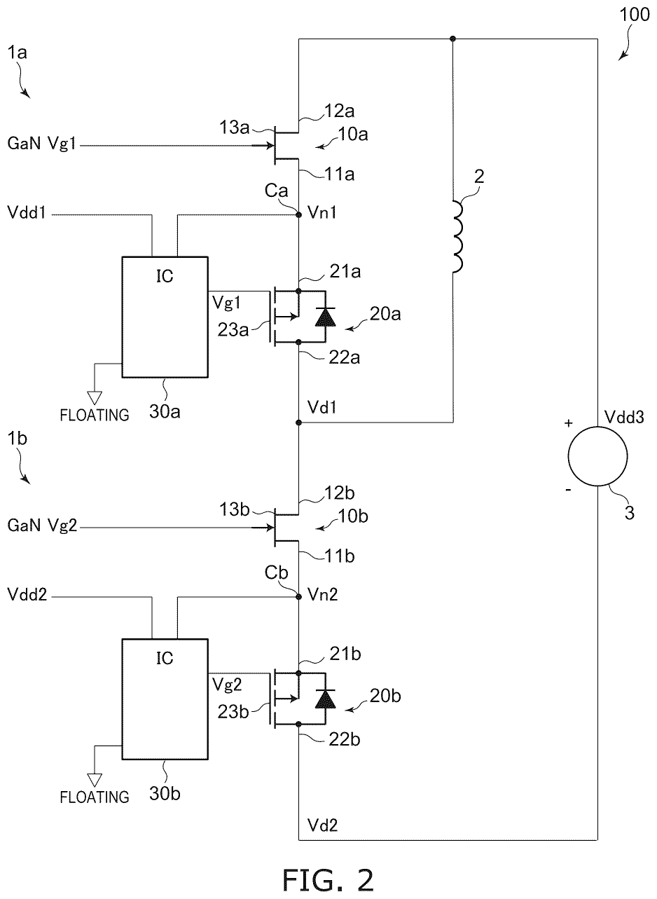

FIG. 2 is a circuit diagram showing a configuration of an electrical circuit according to an embodiment.

Operations of the electrical circuit that uses the semiconductor device according to the embodiment will now be described in more detail with reference to a specific example. The electrical circuit 100 shown in FIG. 2 includes a semiconductor device 1a, a semiconductor device 1b, a coil 2, and a power supply 3. The configurations of the semiconductor devices 1a and 1b are the same as the configuration of the semiconductor device 1. The semiconductor device 1a includes a first semiconductor element 10a and a second semiconductor element 20a. The semiconductor device 1b includes a first semiconductor element 10b and a second semiconductor element 20b.

The semiconductor device 1a, the semiconductor device 1b, and the power supply 3 are connected in series. The semiconductor device 1a is connected to the high-voltage side of the power supply 3. The semiconductor device 1b is connected to the low-voltage side of the power supply 3. A second drain terminal 22a of the second semiconductor element 20a of the semiconductor device 1a is electrically connected to a first drain terminal 12b of the first semiconductor element 10b of the semiconductor device 1b. The semiconductor device 1a and the coil 2 are connected in parallel. A current flows alternately in the semiconductor device 1a and the semiconductor device 1b according to the control of the operations of the first semiconductor element 10a, the first semiconductor element 10b, the second semiconductor element 20a, and the second semiconductor element 20b.

The electrical circuit 100 is applicable to a converter. Generally, in a converter, the first semiconductor element 10a of the high-voltage side and the first semiconductor element 10b of the low-voltage side are alternately turned on. To simplify the description of the gist of the embodiment, an example of switching will be described in which only the first semiconductor element 10b of the low-voltage side is switched on and off.

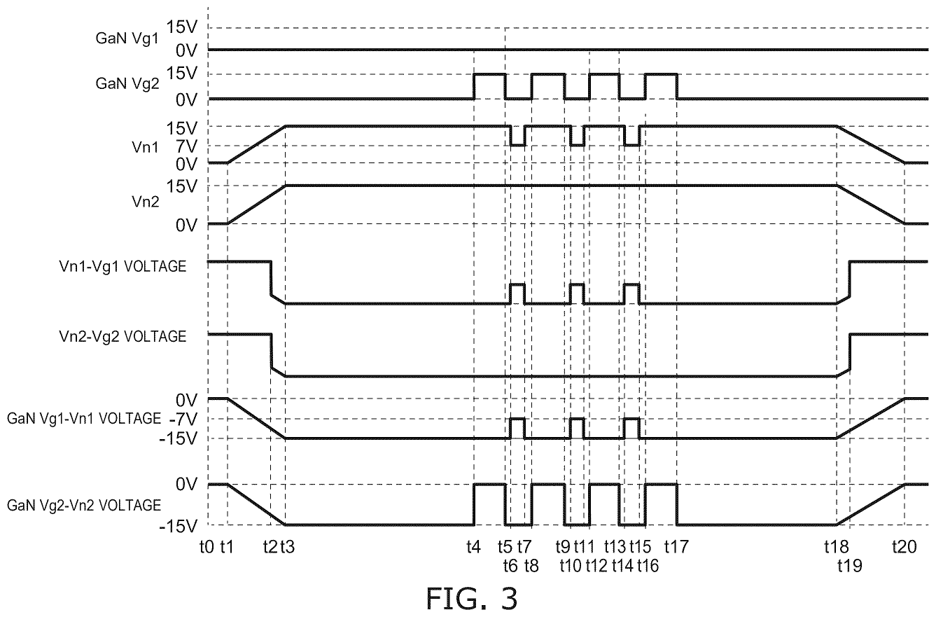

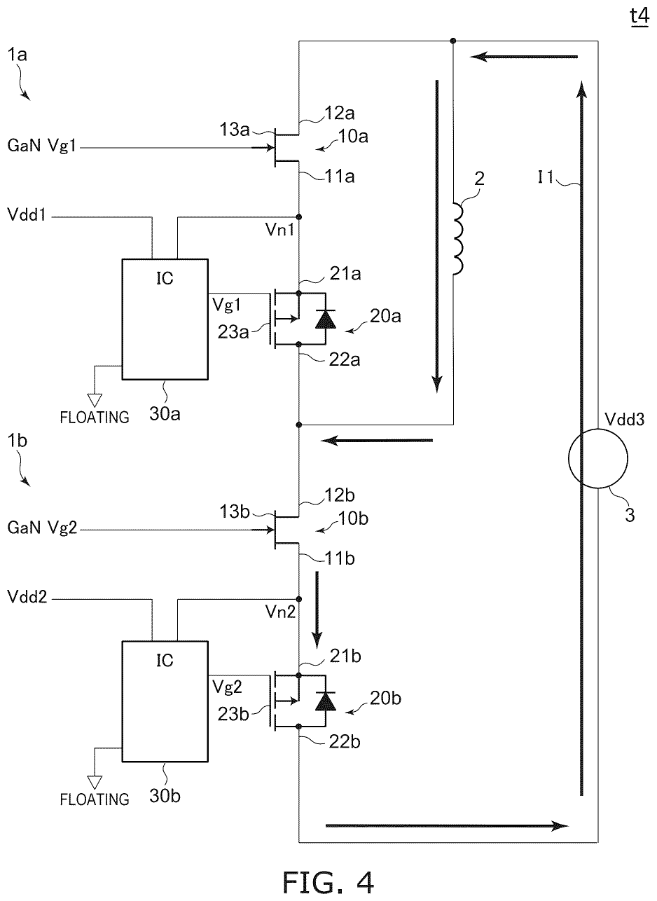

FIG. 3 is a timing chart showing a control of the electrical circuit according to the embodiment. FIGS. 4 to 7 are schematic views showing the flow of currents in the electrical circuit according to the embodiment. In FIGS. 4 to 7, wiring parts for a control circuit 30a to detect the potential of a second source terminal 21a and the potential of the second drain terminal 22a are not illustrated; and wiring parts for a control circuit 30b to detect the potential of a second source terminal 21b and the potential of a second drain terminal 22b are not illustrated.

Among the symbols of the timing chart shown in FIG. 3, as shown in FIG. 2, GaN Vg1 represents the voltage applied to a first gate terminal 13a of the first semiconductor element 10a. GaN Vg2 represents the voltage applied to a first gate terminal 13b of the first semiconductor element 10b. Vn1 represents the voltage of a connection point Ca between a first source terminal 11a of the first semiconductor element 10a and the second source terminal 21a of the second semiconductor element 20a. Vdd1 is supplied to the control circuit 30a. The control circuit 30a controls the supplied Vdd1 and supplies Vn1 to the connection point Ca. Vn2 represents the voltage of a connection point Cb between a first source terminal 11b of the first semiconductor element 10b and the second source terminal 21b of the second semiconductor element 20b. Vdd2 is supplied to the control circuit 30b. The control circuit 30b controls the supplied Vdd2 and supplies Vn2 to the connection point Cb. Vg1 represents the voltage applied to a second gate terminal 23a of the second semiconductor element 20a. Vg2 represents the voltage applied to a second gate terminal 23b of the second semiconductor element 20b.

First, at a timing t0 shown in FIG. 3, GaN Vg1, GaN Vg2, Vn1, and Vn2 each are 0 V. Even when a high voltage is applied to Vdd3 in this state, which is not illustrated shown in FIG. 3, the second semiconductor elements 20a and 20b are in the off-state; therefore, the first semiconductor elements 10a and 10b are in the off-state; and a current does not flow in the electrical circuit 100.

At a timing t1, Vdd1 and Vdd2 are supplied to the control circuit 30a and the control circuit 30b; and Vn1 and Vn2 start to increase. At this time, the second semiconductor element 20a and the second semiconductor element 20b are in the off-state, and so the first semiconductor element 10a and the first semiconductor element 10b continue to be in the off-state.

As Vn1 and Vn2 increase, Vn1 relative to GaN Vg1 and Vn2 relative to GaN Vg2 increase. Up to this point, the control circuits 30a and 30b apply the same voltage as Vn1 to Vg1 and the same voltage as Vn2 to Vg2. Subsequently, from a timing t2 to a timing t3, the control circuit 30a and the control circuit 30b increase the absolute value of Vg1 relative to Vn1 and the absolute value of Vg2 relative to Vn2 to be greater than the absolute values of the thresholds of the second semiconductor elements 20a and 20b. As a result, the second semiconductor element 20a and the second semiconductor element 20b are switched to the on-state. From the timing t1 to the timing t3, Vn1 and Vn2 increase from 0 V to 15 V. 15 V is an example of the first voltage. GaN Vg1 relative to Vn1 and GaN Vg2 relative to Vn2 increase from 0 V to −15 V from the timing t1 to the timing t3. As a result, the first semiconductor element 10a and the first semiconductor element 10b are switched to the off-state.

At a timing t4, GaN Vg2 increases from 0 V to 15 V. GaN Vg2 relative to Vn2 increases from −15 V to 0 V. As a result, the first semiconductor element 10b is switched to the on-state. By switching the first semiconductor element 10b to the on-state, a current I1 flows in the coil 2, the first semiconductor element 10b, and the second semiconductor element 20b as shown in FIG. 4.

At a timing t5, GaN Vg2 is reduced from 15 V to 0 V. GaN Vg2 relative to Vn2 increases from 0 V to −15 V. As a result, the first semiconductor element 10b is switched to the off-state. When the first semiconductor element 10b is turned off, a current flows from the second semiconductor element 20a toward the first semiconductor element 10a due to an inductance component of the electrical circuit 100.

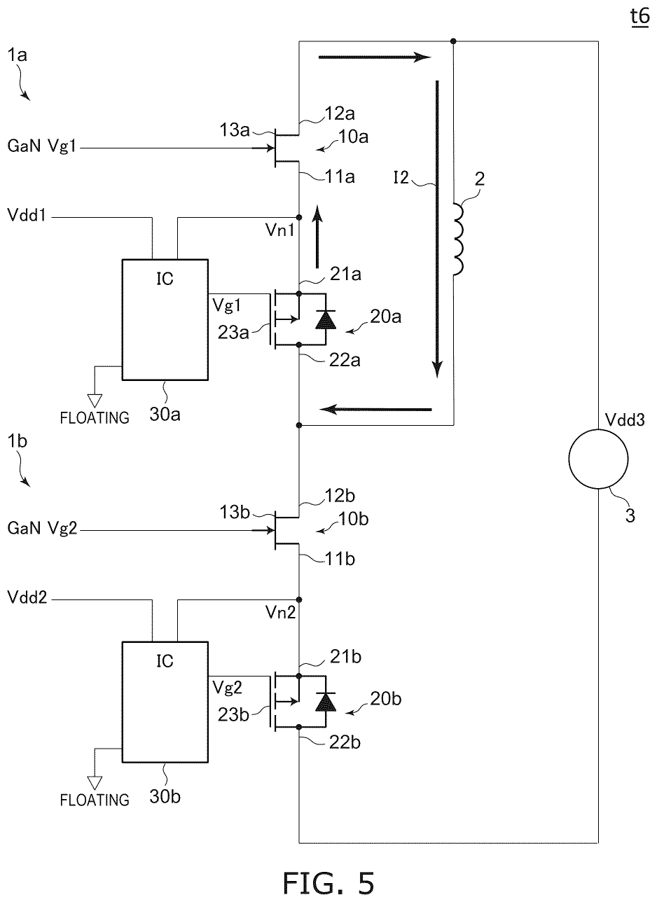

At a timing t6, Vn1 decreases from 15 V to 7 V. 7 V is an example of the second voltage. As a result, GaN Vg1 relative to Vn1 decreases from −15 V to −7 V. −7 V is greater than the threshold voltage of the second semiconductor element 20a. Therefore, the second semiconductor element 20a is in the on-state. Accordingly, as shown in FIG. 5, a current I2 flows in the coil 2, the second semiconductor element 20a, and the first semiconductor element 10a.

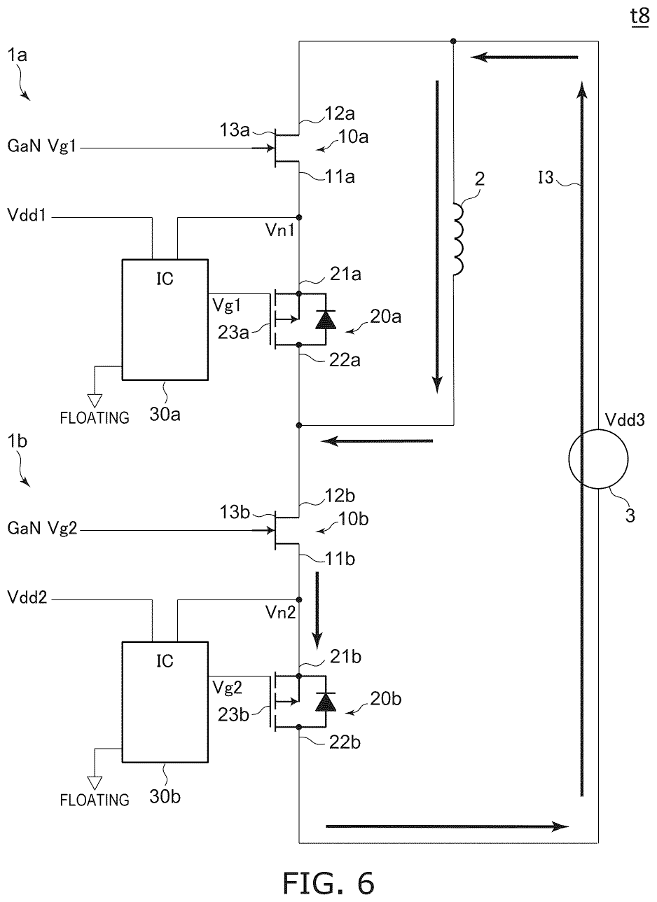

At a timing t7, Vn1 increases from 7 V to 15 V. GaN Vg1 relative to Vn1 also increases from −7 V to −15 V. At timing t8, GaN Vg2 increases from 0 V to 15 V. GaN Vg2 relative to Vn2 decreases from −15 V to 0 V. As a result, the first semiconductor element 10b is switched to the on-state. By switching the first semiconductor element 10b and the second semiconductor element 20b to the on-state, a current I3 flows from the power supply 3 through the coil 2, the first semiconductor element 10b, and the second semiconductor element 20b as shown in FIG. 6.

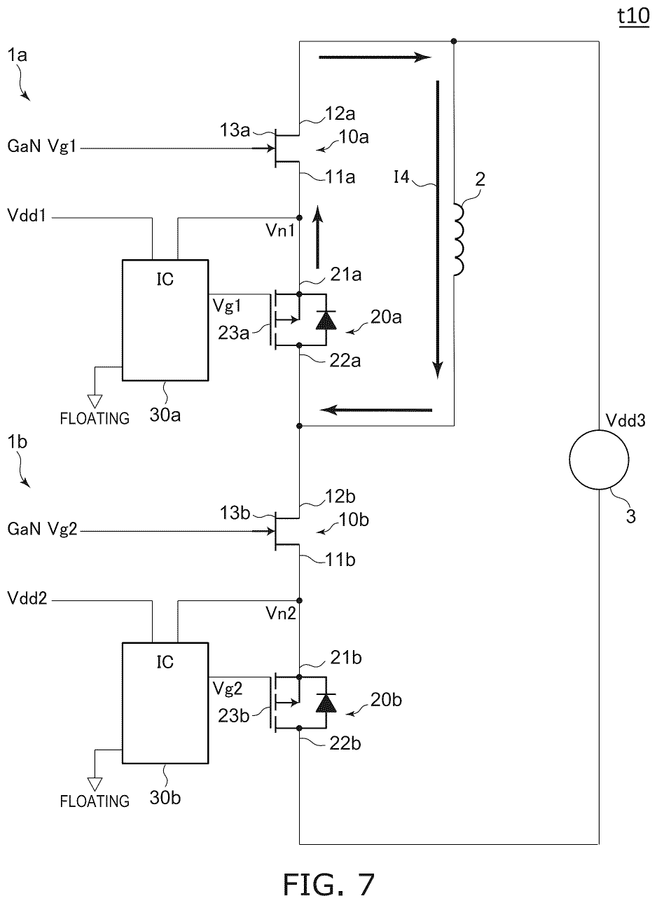

After timing t8, the control of the timings t4 to t7 is re-performed. For example, at the timing t8, similarly to the timing t4, the current I3 flows in the coil 2, the first semiconductor element 10b, and the second semiconductor element 20b as shown in FIG. 6. At a timing t10, similarly to the timing t6, a current I4 flows in the coil 2, the second semiconductor element 20a, and the first semiconductor element 10a as shown in FIG. 7. A control similar to the timings t4 to t7 may be repeated multiple times.

In the example shown in FIG. 3, a control similar to the timings t4 and t5 and a control similar to the timings t6 and t7 are alternately repeated at the timings t8 to t17. An end operation is performed from the timing t17.

Specifically, in the end operation, Vn1 and Vn2 decrease at a timing t18. As a result, the Vn1-Vg1 voltage, the Vn2-Vg2 voltage, Vn1 relative to GaN Vg1, and Vn2 relative to GaN Vg2 decrease. From the timing t18 to a timing t19, the control circuit 30a and the control circuit 30b reduce the absolute value of Vg1 relative to Vn1 and the absolute value of Vg2 relative to Vn2 to be less than the absolute values of the thresholds of the second semiconductor elements 20a and 20b. GaN Vg1 relative to Vn1 and GaN Vg2 relative to Vn2 decrease from −15 V to 0 V from the timing t19 to a timing t20. Thus, the series of operations of the electrical circuit 100 ends.

Advantages of the embodiment will now be described.

When the first semiconductor element 10b of the low-voltage side is turned on and then turned off in the electrical circuit 100, a period (dead time) is created in which the first semiconductor element 10a and the first semiconductor element 10b each are in the off-state. In this period, as shown in FIG. 5, the current I2 that is due to the inductance component flows in the first semiconductor element 10a. It is desirable for the power consumption due to the current I2 to be low.

According to the embodiment, the control circuit 30 changes the voltage of the connection point C between the first source terminal 11 and the second source terminal 21 according to the relationship of the potential of the second source terminal 21 and the potential of the second drain terminal 22. Specifically, the control circuit 30 applies the first voltage to the connection point C in the first state in which the potential of the second source terminal 21 is not less than the potential of the second drain terminal 22. The control circuit 30 applies the second voltage to the connection point C in the second state in which the potential of the second source terminal 21 is less than the potential of the second drain terminal 22. In the second state, the second voltage is less than the first voltage. Also, the absolute value of the difference between the second voltage and the voltage applied to the second gate terminal 23 is greater than the absolute value of the threshold voltage of the second semiconductor element 20.

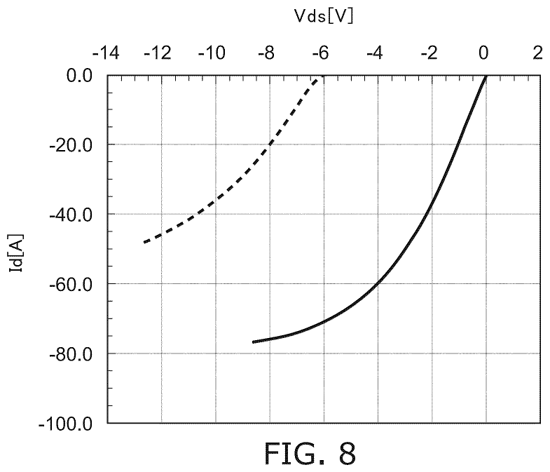

FIG. 8 is a graph showing characteristics of the first semiconductor element.

In FIG. 8, the horizontal axis is a voltage Vds of the first drain terminal 12 relative to the first source terminal 11. The vertical axis is a current Id flowing through the first semiconductor element 10. FIG. 8 shows the relationship of the voltage Vds and the current Id when the current Id flows from the second semiconductor element 20 toward the first semiconductor element 10. The solid line illustrates the relationship when the second voltage is applied to the connection point C in the second state. The broken line illustrates the relationship when the first voltage is applied to the connection point C in the second state. It can be seen from FIG. 8 that the current Id increases as the voltage Vds increases. The product of the voltage Vds and the current Id corresponds to the power consumption. Therefore, to reduce the power consumption during the dead time, it is effective to reduce the voltage Vds.

According to the embodiment, the control circuit 30 applies a relatively large first voltage to the connection point C in the first state in which a current can flow from the second source terminal 21 toward the second drain terminal 22. On the other hand, the control circuit 30 applies a relatively small second voltage to the connection point C in the second state in which a current can flow from the second drain terminal 22 toward the second source terminal 21. In other words, the relatively small second voltage is applied to the connection point C in the dead time. By applying the second voltage to the connection point C in the second state, the voltage Vds can be less than when the first voltage is applied to the connection point C. For example, as shown in FIG. 8, the voltage Vds can be substantially zero. As a result, the power consumption of the first semiconductor element 10 during the dead time can be reduced.

The determination of the first state or the second state may be performed by a processing circuit other than the control circuit 30, or may be performed by the control circuit 30. Favorably, the control circuit 30 performs the determination of the first state or the second state. Because the state is determined by the control circuit 30, it is unnecessary to provide a circuit separately from the control circuit 30. Therefore, the semiconductor device 1 can be smaller.

For example, the control circuit 30 determines the first state or the second state by detecting the potential of the second source terminal 21 and the potential of the second drain terminal 22. Or, the control circuit 30 may determine the first state or the second state by detecting the orientation of the current in the second source terminal 21 or the second drain terminal 22. The detected value that is used to determine the state is arbitrary as long as the first state or the second state can be determined.

It is favorable for the first semiconductor element 10 to include gallium nitride. By using an element that uses gallium nitride as the first semiconductor element 10, the breakdown voltage of the first semiconductor element 10 can be increased, and the on-resistance of the first semiconductor element 10 can be reduced. The second semiconductor element 20 is, for example, a p-type MOSFET that uses single-crystal silicon.

The operations of the control circuit 30 described above may be recorded, as a program that can be executed by a computer, in a magnetic disk (a flexible disk, a hard disk, etc.), an optical disk (CD-ROM, CD-R, CD-RW, DVD-ROM, DVD±R, DVD±RW, etc.), semiconductor memory, or another non-transitory computer-readable storage medium.

For example, the information that is recorded in the recording medium can be read by a computer (a processing circuit). The recording format (the storage format) of the recording medium is arbitrary. For example, the computer reads a program from the recording medium and causes a CPU to execute the instructions recited in the program based on the program. In the computer, the acquisition (or the reading) of the program may be performed via a network.

Embodiments of the invention include the following features.
Feature 1
   a semiconductor device, comprising:
   a first semiconductor element including a first source terminal, a first drain terminal, and a first gate terminal, the first semiconductor element being normally-on;
   a second semiconductor element including a second source terminal, a second drain terminal, and a second gate terminal, the second source terminal being electrically connected to the first source terminal, the second semiconductor element being a p-type MOSFET; and
   a control circuit electrically connected to a connection point between the first source terminal and the second source terminal, the control circuit being configured to
      apply a first voltage to the connection point in a first state in which a potential of the second source terminal is not less than a potential of the second drain terminal, and
      apply a second voltage to the connection point in a second state in which the potential of the second source terminal is less than the potential of the second drain terminal,
   in the second state, the second voltage being less than the first voltage, and an absolute value of a difference between the second voltage and a voltage applied to the second gate terminal being greater than an absolute value of a threshold voltage of the second semiconductor element.
Feature 2

The semiconductor device according to Feature 1, wherein
in the first state, an absolute value of a difference between the first voltage and a potential applied to the first gate terminal is less than an absolute value of a threshold voltage of the first semiconductor element, and
in the second state, the absolute value of the difference between the second voltage and the voltage applied to the second gate terminal is greater than the absolute value of the threshold voltage of the second semiconductor element.
Feature 3

The semiconductor device according to Feature 1 or 2, wherein
the control circuit is configured to detect the potential of the second source terminal and the potential of the second drain terminal, and
the control circuit is configured to determine the first state or the second state based on the potential of the second source terminal and the potential of the second drain terminal that are detected.
Feature 4

The semiconductor device according to any one of Features 1 to 3, wherein
the control circuit is configured to detect an orientation of a current flowing in the second source terminal or the second drain terminal, and
the control circuit is configured to determine the first state or the second state based on the orientation that is detected.
Feature 5

The semiconductor device according to any one of Features 1 to 4, wherein
the first semiconductor element includes gallium nitride.
Feature 6

A control circuit,
the control circuit being electrically connected to a connection point between a first source terminal of a first semiconductor element and a second source terminal of a second semiconductor element,
the first semiconductor element being normally-on,
the second semiconductor element being a p-type MOSFET,
the control circuit being configured to:
   apply a first voltage to the connection point when a potential of the second source terminal is not less than a potential of a second drain terminal of the second semiconductor element; and
   apply a second voltage to the connection point when the potential of the second source terminal is less than the potential of the second drain terminal,
the second voltage being less than the first voltage,
an absolute value of a difference between the second voltage and a voltage applied to a second gate terminal of the second semiconductor element being greater than an absolute value of a threshold voltage of the second semiconductor element.
Feature 7

A control method of a semiconductor device,
the semiconductor device including:
   a first semiconductor element including a first source terminal and a first drain terminal, the first semiconductor element being normally-on; and
   a second semiconductor element including a second source terminal and a second drain terminal, the second source terminal being electrically connected to the first source terminal, the second semiconductor element being a p-type MOSFET,
the control method comprising:
   applying a first voltage to a connection point between the first source terminal and the second source terminal when a potential of the second source terminal is not less than a potential of the second drain terminal; and
   applying a second voltage to the connection point when the potential of the second source terminal is less than the potential of the second drain terminal,
the second voltage being less than the first voltage,
an absolute value of a difference between the second voltage and a voltage applied to a second gate terminal of the second semiconductor element being greater than an absolute value of a threshold voltage of the second semiconductor element.
Feature 8

A program that, when executed by a computer, causes the computer to perform the control method according to Feature 7.
Feature 9

A storage medium storing the program according to Feature 8.

According to the embodiments above, a semiconductor device, a control circuit, a control method of a semiconductor device, a program, and a storage medium that can reduce the power consumption are provided.

While certain embodiments of the inventions have been illustrated, these embodiments have been presented by way of example only, and are not intended to limit the scope of the inventions. These novel embodiments may be embodied in a variety of other forms; and various omissions, substitutions, modifications, etc., can be made without departing from the spirit of the inventions. These embodiments and their modifications are within the scope and spirit of the inventions, and are within the scope of the inventions described in the claims and their equivalents. The embodiments above can be implemented in combination with each other.

What is claimed is:

1. A semiconductor device, comprising:
a first semiconductor element including a first source terminal, a first drain terminal, and a first gate terminal, the first semiconductor element being normally-on;
a second semiconductor element including a second source terminal, a second drain terminal, and a second gate terminal, the second source terminal being electrically connected to the first source terminal, the second semiconductor element being a p-type MOSFET; and
a control circuit electrically connected to a connection point between the first source terminal and the second source terminal, the control circuit being configured to
apply a first voltage to the connection point in a first state in which a potential of the second source terminal is not less than a potential of the second drain terminal, and
apply a second voltage to the connection point in a second state in which the potential of the second source terminal is less than the potential of the second drain terminal,
in the second state, the second voltage being less than the first voltage, and an absolute value of a difference between the second voltage and a voltage applied to the second gate terminal being greater than an absolute value of a threshold voltage of the second semiconductor element.

2. The semiconductor device according to claim 1, wherein
in the first state, an absolute value of a difference between the first voltage and a potential applied to the first gate terminal is less than an absolute value of a threshold voltage of the first semiconductor element, and
in the second state, the absolute value of the difference between the second voltage and the voltage applied to the second gate terminal is greater than the absolute value of the threshold voltage of the second semiconductor element.

3. The semiconductor device according to claim 1, wherein
the control circuit is configured to detect the potential of the second source terminal and the potential of the second drain terminal, and
the control circuit is configured to determine the first state or the second state based on the potential of the second source terminal and the potential of the second drain terminal that are detected.

4. The semiconductor device according to claim 1, wherein
the control circuit is configured to detect an orientation of a current flowing in the second source terminal or the second drain terminal, and
the control circuit is configured to determine the first state or the second state based on the orientation that is detected.

5. The semiconductor device according to claim 1, wherein
the first semiconductor element includes gallium nitride.

6. A control circuit,
the control circuit being electrically connected to a connection point between a first source terminal of a first semiconductor element and a second source terminal of a second semiconductor element,
the first semiconductor element being normally-on,
the second semiconductor element being a p-type MOSFET,
the control circuit being configured to:
apply a first voltage to the connection point when a potential of the second source terminal is not less than a potential of a second drain terminal of the second semiconductor element; and
apply a second voltage to the connection point when the potential of the second source terminal is less than the potential of the second drain terminal,
the second voltage being less than the first voltage,
an absolute value of a difference between the second voltage and a voltage applied to a second gate terminal of the second semiconductor element being greater than an absolute value of a threshold voltage of the second semiconductor element.

7. A control method of a semiconductor device,
the semiconductor device including:
a first semiconductor element including a first source terminal and a first drain terminal, the first semiconductor element being normally-on; and
a second semiconductor element including a second source terminal and a second drain terminal, the second source terminal being electrically connected to the first source terminal, the second semiconductor element being a p-type MOSFET,
the control method comprising:
applying a first voltage to a connection point between the first source terminal and the second source terminal when a potential of the second source terminal is not less than a potential of the second drain terminal; and
applying a second voltage to the connection point when the potential of the second source terminal is less than the potential of the second drain terminal,
the second voltage being less than the first voltage,
an absolute value of a difference between the second voltage and a voltage applied to a second gate terminal of the second semiconductor element being greater than an absolute value of a threshold voltage of the second semiconductor element.

8. A non-transitory computer-readable storage medium storing a program that, when executed by a computer, causes the computer to perform the control method according to claim 7.
